(19) United States
(12) Patent Application Publication
(10) Pub. No.: US 2026/0052786 A1
(43) Pub. Date: Feb. 19, 2026

(54) Image Sensing Module with an Extending Substrate

(71) Applicant: OmniVision Technologies, Inc., Santa Clara, CA (US)

(72) Inventors: Jau-Jan DENG, Taipei (TW); Wei-Ping CHEN, New Taipei City (TW); Tsung-Wei WAN, Hsin Chu City (TW)

(21) Appl. No.: 18/804,588

(22) Filed: Aug. 14, 2024

(51) Int. Cl. H01L 27/146

(52) U.S. Cl. CPC H10F 39/804; H10F 39/8063

(57) ABSTRACT

An image sensing module includes an extending substrate. An image sensor and a lens module are respectively formed on the first surface and the second surface of the extending substrate. The width of the extending substrate is wider than the width of the image sensor to improve dimension mismatches between the lens module and the image sensor. An enclosure is formed on the lower surface of the extending substrate to prevent lights from entering into the sensing area of the image sensor from the sidewall of the image sensor. Sealing glues are adhered between the image sensor and the enclosure.

### TECHNICAL FIELD

The present invention relates to image sensing technologies, and more particularly, an image sensing module with an extending substrate.

### BACKGROUND

Image sensors may convert incident light into electrical signals. CMOS image sensors dominate in consumer goods due to overall cost is usually cheaper and they have lower power consumption. Cost-effective CMOS image sensors are widely used in mobile handsets, smart phones and digital cameras. Typically, the image sensor includes a light sensing array with pixels configurated in two-dimensions. Each pixel in the array works with lenses to respond to the incident light. Outputs from the pixels are converted to form raw data which can be processed by a processor to produce digital images.

High-speed and ultra-high-definition resolution are also growing demands from markets. How to fit the demands without increasing the cost is another issue. As known in the art, the CMOS image sensor typically includes a pixel area and a logic area. In the pixel area, each pixel may include one photodiode and a plurality of pixel transistors. In the logic area, logic elements are configurated to process signals from the pixel area. The CMOS image sensor may have a structure in which the pixel area and the logic area are formed in respective chips, i.e., the chips are stacked in some examples. A stacked CMOS image sensor may provide high image quality through maximization of the number of pixels. Some CMOS image sensors use back-side illumination to increase the number of photons that hit the photodiode.

In the past decades, one of manufacture trends is to shrink the size of chips. For example, the chips have been evolving towards smaller size, starting from the initial 0.35 micrometers to 0.13 micrometers . . . 0.45 nanometers . . . and now to 3 nanometers. In general, transistor sizes are used to distinguish chip manufacturing processes. Smaller chips offer more pronounced advantages, for example, smaller transistor allows for higher density, with more transistors, the chips can perform more calculations, in terms of making them more powerful. As the transistors get smaller, the distance between devices decreases, which results in faster data transfer.

On the other hand, a lens module is required for an optical system. Various lenses may be used for different domains and purposes. For example, zoom lenses are commonly used with the smart phones, the digital cameras and other optical instruments. Some photographic lenses are long-focus lenses, some are wide-angle lenses, and others cover a range from wide-angle to long-focus. For instance, some mobile phones were equipped with a 100× zoom lens in previous years. In recent years, the capabilities of the smart phones have tended to super-telephoto. In addition to the wide-angle lens, the mainstream smart phones usually have ultra-wide-angle and telephoto lenses.

The lens module is provided with larger size to gain better performances in some applications. However, this situation is on the contrary to the chip shrinking trends. For example, wafer level lenses have large diagonal field of views (DFOV) and excellent performances, but they have larger sizes. Consequently, some dimension mismatch shortcomings are observed. The size mismatch between the lens module and the image sensor will cause overhangs. It means that the dimension of the lens module is wider than that of the image sensor. Gaps are formed between the lens module and the image sensor. In some cases, small overhangs will cause light leakages, therefore, black glues are required to seal the gaps caused by the overhangs to avoid the light leakage drawbacks. If the overhangs cause serious issues, the wafer level lens will lose its advantage, namely, a plastic holder is necessary to carry the image sensor if the image sensor size is far smaller than the size of the lens module. Further, under the conventional structure, the image sensor may be bent with some certain degrees, it raises filter spectrum shift issues while the light enters with large angels. Therefore, what is desired is a novel scheme to solve the aforementioned issues.

### SUMMARY OF THE INVENTION

In one aspect of the present invention, the present invention discloses an image sensing module including an extending substrate. An image sensor is formed on the first surface of the extending substrate. A lens module is formed on the second surface of the extending substrate, the width of the extending substrate is wider than the width of the image sensor to improve or compensate dimension mismatches between the lens module and the image sensor. In one embodiment, an enclosure is formed on the lower surface of the extending substrate to prevent lights from entering into the sensing area of the image sensor from the sidewall of the image sensor. The enclosure includes a spacer formed adjacent to the image sensor. Sealing glues are adhered between the image sensor and the enclosure.

In another aspect of the present invention, the width of the lens module is between the width of the extending substrate and the width of the image sensor to improve the dimension mismatches between the lens module and the image sensor.

Preferably, the extending substrate may reduce filter spectrum shifts and it is formed of glass, quartz, plastic or the combination thereof. An infrared (IR) cutting layer or an IR passing layer is formed on the extending substrate. The lens module includes a wafer level lens, and the image sensor includes a CSP (chip scale package). Alternatively, the extending substrate includes a stacked configuration.

### BRIEF DESCRIPTION OF THE DRAWINGS

The components, characteristics and advantages of the present invention may be understood by the detailed descriptions of the preferred embodiments outlined in the specification and the drawings attached:

FIG. 1 illustrates a schematic diagram of an image sensing module with an extending substrate according to one embodiment of the present invention.

FIG. 2 illustrates a schematic diagram of an image sensing module with an extending substrate having a stacked configuration according to one embodiment of the present invention.

FIG. 3 illustrates steps of assembling the image sensing module of FIG. 1 according to one embodiment of the present invention.

FIG. 4 illustrates steps of assembling the image sensing module of FIG. 2 according to one embodiment of the present invention.

### DETAILED DESCRIPTION

Some preferred embodiments of the present invention will now be described in greater detail. However, it should be recognized that the preferred embodiments of the present invention are provided for illustration rather than limiting the present invention. In addition, the present invention can be practiced in a wide range of other embodiments besides those explicitly described, and the scope of the present invention is not expressly limited except as specified in the accompanying claims.

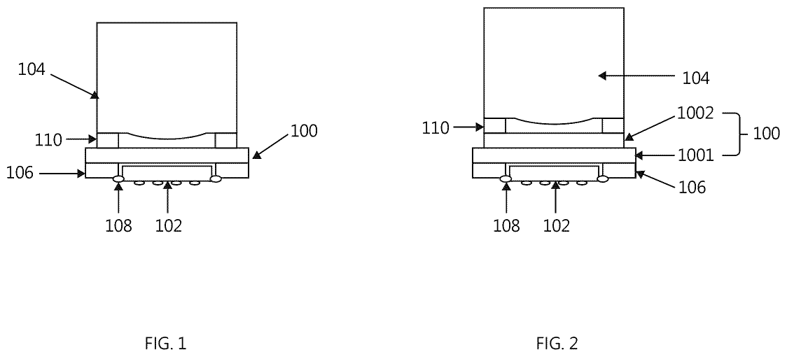

The present invention discloses an image sensing module having an extending substrate 100 as shown in FIG. 1. An image sensor 102 is formed on the first surface of the extending substrate 100, while a lens module 104 is formed on the second surface of the extending substrate 100. The first surface is opposite to the second surface. In one embodiment, the first surface refers to the lower surface of the extending substrate 100, while the second surface is the upper surface of the extending substrate 100. The image sensor 102 could be any kind of sensor, for example, CCDs or CMOS image sensors.

The width of the extending substrate 100 is wider than the width of the image sensor 102 to improve dimension mismatches between the lens module 104 and the image sensor 102. In one embodiment, the wider extending substrate 100 may compensate the dimension mismatches between the elements mentioned above, thereby eliminating the bending issue of the prior art. Consequently, the extending substrate 100 reduces the filter spectrum shift caused by the dimension mismatch of the prior arts. In one case, the lens module 104 is formed on the second surface of the extending substrate 100, the width (or diameter) of the lens module 104 is between the width of the extending substrate 100 and the width of the image sensor 102 to solve the aforementioned mismatch issues.

Preferably, an enclosure 106 is formed on the first (lower) surface of the extending substrate 100 to prevent lights from entering into the sensing area of the image sensor 102 from sidewalls of the image sensor 102. In one embodiment, the enclosure 106 is a spacer formed adjacent to the image sensor 102. Sealing glues 108 are adhered between the image sensor 102 and the enclosure (spacer) 106. The sealing glues 108 can be partially refilled into the gaps formed between the enclosure 106 and the image sensor 102 to prevent light or moisture from entering. Preferably, the extending substrate 100 is transparent and formed of glass, quartz, plastic or the combination thereof. The enclosure (spacer) 106 could be formed of resin, polymer, rubber, epoxy, ceramic or the combination thereof. An infrared (IR) cutting layer or an IR passing layer is formed on the lower or the upper surface of the extending substrate 100.

An engagement element 110 is provided to connect the extending substrate 100 with the lens module 104. Typically, the engagement element 110 is located at the edges of the lens module 104, thereby forming a cavity under the lens module 104 to expose the image sensor 102. The size of the cavity is preferably larger than the dimension of the sensing area of the image sensor 102, such that light from the lens module 104 can be received by the sensing area. Preferably, the height, width, shape or diameter of the engagement element 110 may be modified to fit optical parameters, such as focal length, of the lens module 104.

Alternatively, please refer to FIG. 2, the extending substrate 100 includes a stacked configuration having two sub-substrates, namely, an upper (first) sub-substrate 1002 is stacked on a lower (second) sub-substrate 1001. The upper sub-substrate 1002 and the lower sub-substrate 1001 are formed of glass, quartz, plastic or the combination thereof. Preferably, the infrared (IR) cutting layer or the IR passing layer may be formed on the lower or the upper surface of the upper (first) sub-substrate 1002. In another case, the infrared (IR) cutting layer or the IR passing layer may be formed on the lower or the upper surface of the lower (second) sub-substrate 1001. In one example, the length of the lower (second) sub-substrate 1001 is longer than the one of the upper (first) sub-substrate 1002. The dimension of the upper (first) sub-substrate 1002 may be fit to the width (or diameter) of the lens module 104. In one case, any sub-substrate may be used to adjust optical parameters for other elements such as the lens module 104 or the image sensor 102. The exemplary structure of FIG. 2 includes all or part of the features, characteristics of the embodiment shown in FIG. 1.

Preferably, the lens module 104 includes at least one wafer level lens which is transmissive to light in a wavelength range of interest. The wafer level lens is manufactured using wafer level technologies which involve steps of forming lenses on a wafer. Subsequently, the wafer is diced to produce individual wafer level lenses. In one example, one or more lens elements are arranged together in the wafer level lens. The wafer level lens provides additional degrees of freedom in lens designs, as compared to a conventional injection molded lens.

The shapes of the lens elements may be different. For example, the lens surfaces may be convex, concave, a combination of convex and concave, and/or have aspheric properties. In one embodiment, the lens elements are composed of different respective materials to improve performance aspects of the wafer level lens. For example, the materials of the lens minimize an optical aberration, such as chromatic aberration, spherical aberration, or distortion, in some embodiments. Additionally, the wafer level manufacturing is well-suited for mass production and generally associated with reduced cost.

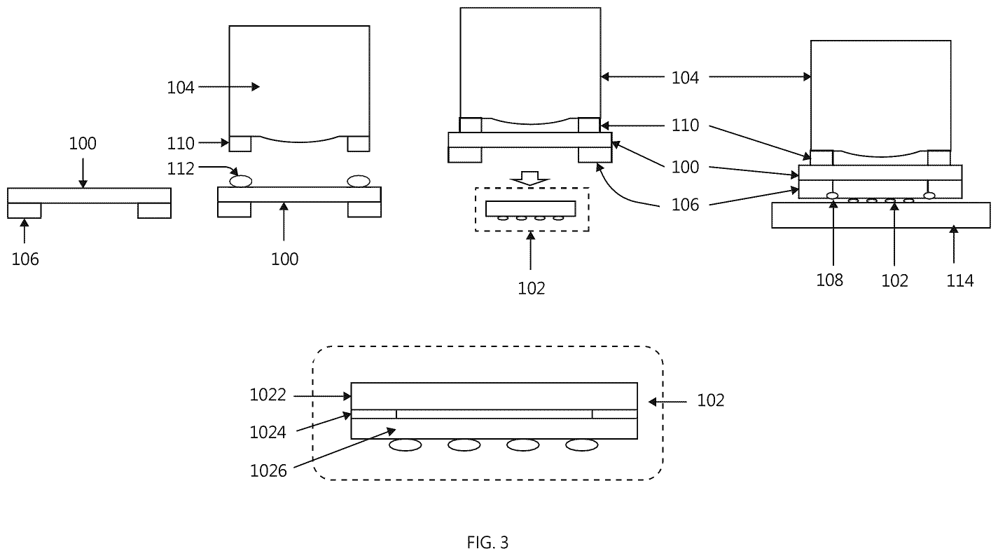

It is advantageous to assemble the extending substrate 100 with the lens module 104 prior to attaching the image sensor 102 with the extending substrate 100. However, the procedure order may be altered without departure from the scope of the present invention. The assembling procedure is shown in FIG. 3, the extending substrate 100 is provided with the enclosure 106 formed under the extending substrate 100. The enclosure 106 is attached to the extending substrate 100, followed by engaging the extending substrate 100 with the lens module 104. The lens module 104 is placed over the extending substrate 100 by the engagement element 110. Before engagement, adhesion material 112 is placed on the extending substrate 100 and aligned with the engagement element 110. A curing procedure may be required after adhesion. Subsequently, the image sensor 102 is disposed within the cavity formed by the enclosure 106, and the image sensor 102 is attached under the extending substrate 100 by glues. During the step, a process or method maybe used to facilitate alignment of the lens module 104 with the image sensor 102. The sealing glues 108 are subsequently adhered between the image sensor 102 and the enclosure (spacer) 106. Preferably, the sealing glues 108 are partially refilled into gaps between the image sensor 102 and the enclosure 106 to prevent light or moisture from entering.

Next, the image sensor 102 is mounted on a PCB (printed circuit board) 114 through balls or other connection elements. In one embodiment, the image sensor 102 is a chip-scale package (CSP) with a ball grid array (BGA). The image sensor 102 may include a transparent cover 1022 formed on a sensor die 1026 with a dam material 1024 adhered in-between. The transparent cover 1022 may be formed of glass, quartz, plastic or the combination thereof. The BGA provides more contacts and shorter traces, leading to better performance at high speeds. The image sensor 102 is placed on the PCB 114 with conductive pads that matches the balls of the image sensor 102. In other case, balls may be used on both the PCB 114 and the image sensor 102. A thermal process is then performed, either in a reflow oven or by an infrared heater. Surface tension causes the molten solder to hold the package in alignment with the PCB 114, while the solder cools and solidifies, forming soldered connections between the image sensor 102 and the PCB 114.

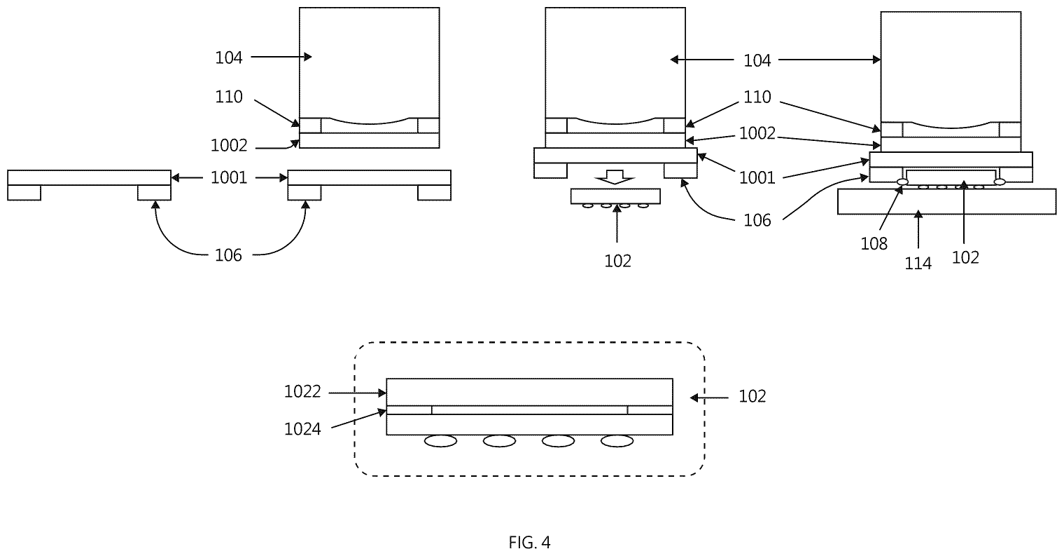

FIG. 4 illustrates steps of assembling the image sensing module of FIG. 2, in the embodiment, the upper sub-substrate 1002 is attached under the lens module 104, while the lower sub-substrate 1001 is engaged with the enclosure 106. These steps maybe performed simultaneously or at different times. The lens module 104 is placed over the upper sub-substrate 1002 via the engagement element 110. Subsequently, the upper sub-substrate 1002 is adhered with the lower sub-substrate 1001 together. A curing procedure may be required after adhesion. Next, the image sensor 102 is attached under the lower sub-substrate 1001. The following steps to form the sealing glues 108, and to mount the image sensor 102 on the PCB 114 are similar to the embodiment illustrated in FIG. 3. Therefore, redundancy descriptions are omitted.

Apparently, the present invention solves the issue of the dimension mismatch between the lens module 104 and the image sensor 102 by introducing the extending substrate 100. The light leakage from the convention sensor sidewalls is eliminated at the same time. Obviously, filter spectrum shifts due to large AOI (angle of incidence) are also reduced by the novel structure of the present invention. No focus match capability issue will be induced for flat bottom lens modules.

Spatially relative terms, such as “lower”, “under”, “over”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. Thus, the terms “under” may encompass both an orientation of above and below. The terms “adhered”, “engaged” and “connected,” along with their derivatives, may be used. It should be understood, these terms may be used to indicate that two or more elements are in direct physical contact with each other. However, these terms may also mean that two or more elements are not in direct contact with each other, but yet still cooperate or interact with each other.

While various embodiments of the present invention have been described above, it should be understood that they have been presented by a way of example and not limitation. Numerous modifications and variations within the scope of the invention are possible. The present invention should only be defined in accordance with the following claims.

What is claimed is:

1. An image sensing module, comprising:
an extending substrate;
an image sensor formed on a first surface of said extending substrate;
a lens module formed on a second surface of said extending substrate; and
wherein a first width of said extending substrate is wider than a second width of said image sensor to improve a dimension mismatch between said lens module and said image sensor.

2. The image sensing module of claim 1, further comprising an enclosure formed on said first surface of said extending substrate to prevent lights from entering into a sensing area of said image sensor from a sidewall of said image sensor.

3. The image sensing module of claim 2, wherein said enclosure includes a spacer formed adjacent to said image sensor.

4. The image sensing module of claim 3, further comprising a sealing glue adhered between said image sensor and said spacer.

5. The image sensing module of claim 1, wherein said extending substrate is formed of glass, quartz, plastic or the combination thereof.

6. The image sensing module of claim 1, wherein said extending substrate includes an infrared (IR) cutting layer or an IR passing layer formed thereon.

7. The image sensing module of claim 1, wherein said extending substrate includes a first sub-substrate stacking on a second sub-substrate, wherein said first sub-substrate and said second sub-substrate are formed of glass, quartz, plastic or the combination thereof.

8. The image sensing module of claim 7, wherein said first sub-substrate includes an infrared (IR) cutting layer or an IR passing layer formed thereon.

9. The image sensing module of claim 1, wherein said extending substrate is employed to reduce a filter spectrum shift.

10. The image sensing module of claim 1, wherein said image sensor includes a cover formed of glass, quartz, plastic or the combination thereof.

11. The image sensing module of claim 1, wherein said lens module includes a wafer level lens, wherein said image sensor includes a CSP (chip scale package).

12. An image sensing module, comprising:
an extending substrate;
an image sensor formed on a first surface of said extending substrate;
a lens module formed on a second surface of said extending substrate, wherein a first width of said lens module is between a second width of said extending substrate and a third width of said image sensor to improve a dimension mismatch between said lens module and said image sensor; and
an enclosure formed on said first surface of said extending substrate to prevent lights from entering into a sensing area of said image sensor from a sidewall of said image sensor.

13. The image sensing module of claim 12, wherein said enclosure includes a spacer formed adjacent to said image sensor.

14. The image sensing module of claim 13, further comprising a sealing glue adhered between said image sensor and said spacer.

15. The image sensing module of claim 12, wherein said extending substrate is formed of glass, quartz, plastic or the combination thereof.

16. The image sensing module of claim 12, wherein said extending substrate includes an infrared (IR) cutting layer or an IR passing layer formed thereon.

17. The image sensing module of claim 12, wherein said extending substrate includes a first sub-substrate stacking on a second sub-substrate, wherein said first sub-substrate and said second sub-substrate are formed of glass, quartz, plastic or the combination thereof.

18. The image sensing module of claim 17, wherein said first sub-substrate includes an infrared (IR) cutting layer or an IR passing layer formed thereon.

19. The image sensing module of claim 12, wherein said extending substrate is employed to reduce a filter spectrum shift.

20. The image sensing module of claim 12, wherein said image sensor includes a cover formed of glass, quartz, plastic or the combination thereof.

21. The image sensing module of claim 12, wherein said lens module includes a wafer level lens, wherein said image sensor includes a CSP (chip scale package).
